(19) United States
(12) Patent Application Publication
(10) Pub. No.: US 2015/0307989 A1
(43) Pub. Date: Oct. 29, 2015

(54) ATOMIC LAYER DEPOSITION METHOD AND APPARATUSES

(71) Applicant: Sven Lindfors, Espoo (FI)

(72) Inventor: Sven Lindfors, Espoo (FI)

(73) Assignee: Picosun Oy, Espoo (FI)

(21) Appl. No.: 14/386,504

(22) PCT Filed: Mar. 23, 2012
(86) PCT No.: PCT/FI2012/050296

§ 371 Date: Sep. 19, 2014

(51) Int. Cl. C23C 16/455; C23C 16/46

(52) U.S. Cl. CPC C23C 16/45527; C23C 16/45544; C23C 16/46

(57) ABSTRACT

A method includes operating an atomic layer deposition reactor configured to deposit material on at least one substrate by sequential self-saturating surface reactions, and using dry air in the reactor as purge gas.

### FIELD

The aspects of the disclosed embodiments generally relate to deposition reactors. More particularly, but not exclusively, the disclosed embodiments relate to such deposition reactors in which material is deposited on surfaces by sequential self-saturating surface reactions.

### BACKGROUND

Atomic Layer Epitaxy (ALE) method was invented by Dr. Tuomo Suntola in the early 1970's. Another generic name for the method is Atomic Layer Deposition (ALD) and it is nowadays used instead of ALE. ALD is a special chemical deposition method based on the sequential introduction of at least two reactive precursor species to at least one substrate.

Thin films grown by ALD are dense, pinhole free and have uniform thickness. For example, in an experiment aluminum oxide has been grown by thermal ALD from trimethylaluminum (CH₃)₃Al, also referred to as TMA, and water at 250-300° C. resulting in only about 1% non-uniformity over a substrate wafer.

Typical ALD reactors are quite complex apparatuses. Accordingly, there is an ongoing need to produce solutions that would simplify either the apparatuses themselves or their use.

### SUMMARY

According to a first example aspect of the invention there is provided a method comprising:

operating an atomic layer deposition reactor configured to deposit material on at least one substrate by sequential self-saturating surface reactions; and

using dry air in the reactor as purge gas.

In certain example embodiments, dry air flows (or is configured to flow) along a purge gas in-feed line. In certain example embodiments, dry air as purge gas flows from an inactive gas source via a purge gas in-feed line into a reaction chamber.

In certain example embodiments, the method comprises: using dry air as carrier gas.

In certain example embodiments, dry air flows (or is configured to flow) along a precursor vapor in-feed line. In certain example embodiments, this may occur during ALD processing. In certain example embodiments, dry air as carrier gas flows from an inactive gas source via a precursor source into a reaction chamber. In certain example embodiments, dry air as carrier gas is used to increase the pressure in the precursor source. In certain other embodiments, dry air as carrier gas flows from an inactive gas source via a precursor vapor in-feed line into a reaction chamber without passing the precursor source. The flow route may be designed based on whether the vapor pressure of the precursor vapor in itself is high enough, or whether the pressure should be increased by an inactive gas flow to the precursor source.

A single dry air source or a plurality of dry air sources may be used. Dry air (or dried air) in this context means air with no moisture residue. Dry air may be compressed gas. It may be used to carry precursor from a precursor source into a reaction chamber.

In certain example embodiments, the method comprises: having dry air to flow into a reaction chamber of the reactor during the whole deposition sequence. A deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B).

In certain example embodiments, reaction chamber heating is implemented at least in part via conducting heated dry air into the reaction chamber. This may occur during an initial purge and/or during deposition ALD processing (deposition).

Accordingly, in certain example embodiments, the method comprises: using dry air in heating a reaction chamber of the reactor.

In certain example embodiments, the method comprises: heating the dry air downstream a purge gas in-feed valve.

In certain example embodiments, the method comprises: providing a feedback connection of heat from an outlet part of the reactor to a purge gas in-feed line heater.

In certain example embodiments, the outlet part comprises a heat exchanger. The outlet part may be an outlet part of the reaction chamber of the reactor. The outlet part may be a gas outlet part.

In certain example embodiments, the method comprises: operating said atomic layer deposition reactor in ambient pressure.

In such embodiments, a vacuum pump is not needed.

In certain example embodiments, the method comprises: using an ejector attached to an outlet part of the reactor to reduce operating pressure in the reactor.

An ejector can be used instead of a vacuum pump when it is required to operate below the ambient pressure but a vacuum is not needed. The outlet part may be a reactor chamber lid. The ejector may be a vacuum ejector attached to the lid or to exhaust channel.

The inlet of gases into the reaction chamber may be on the bottom side of the reaction chamber and the outlet of reaction residue may be on the top side of the reaction chamber. Alternatively, the inlet of gases into the reaction chamber may be on the top side of the reaction chamber and the outlet of reaction residue may be on the bottom side of the reaction chamber

In certain example embodiments, the reaction chamber is lightweight. A pressure vessel as a reaction chamber is not needed.

According to a second example aspect of the invention there is provided an apparatus comprising:

an atomic layer deposition reaction chamber configured to deposit material on at least one substrate by sequential self-saturating surface reactions; and
a dry air in-feed line from a dry air source to feed dry air as purge gas into a reaction chamber of the reactor.

The apparatus may be an atomic layer deposition (ALD) reactor.

In certain example embodiments, the apparatus comprises:

a precursor in-feed line from a dry air source via a precursor source into the reaction chamber to carry precursor vapor into the reaction chamber.

In certain example embodiments, the apparatus comprises a heater configured to heat the dry air. In certain example embodiments, the apparatus comprises said heater downstream a purge gas in-feed valve.

In certain example embodiments, the apparatus comprises a feedback connection of heat from an outlet part of the reactor to a purge gas in-feed line heater. In certain example embodiments, the outlet part comprises a heat exchanger. The outlet part may be an outlet part of the reaction chamber of the reactor. The outlet part may be a gas outlet part.

In certain example embodiments, the reactor is a lightweight reactor configured to operate in ambient pressure or close to the ambient pressure. The lightweight reactor may be without a vacuum pump. Close to the ambient pressure means that the pressure may be a reduced pressure, but not a vacuum pressure. In these embodiments, the reactor may have thin walls. In certain example embodiments, atomic layer deposition is carried out without a vacuum pump. Also, in certain example embodiments, atomic layer deposition is carried out without a pressure vessel. Accordingly, the lightweight (light-structured) reactor in certain example embodiments is implemented with a lightweight (light-structured) reaction chamber without a pressure vessel.

In certain example embodiments, the apparatus comprises: an ejector attached to an outlet part of the reactor to reduce operating pressure in the reactor.

An ejector can be used instead of a vacuum pump when it is required to operate below the ambient pressure but a vacuum is not needed. The outlet part may be a reactor chamber lid. The ejector may be a vacuum ejector attached to the lid or to exhaust channel.

According to a third example aspect of the invention there is provided a production line comprising the apparatus of the second aspect as a part of the production line.

According to a fourth example aspect of the invention there is provided an apparatus comprising:

means for operating an atomic layer deposition reactor configured to deposit material on at least one substrate by sequential self-saturating surface reactions; and
means for using dry air in the reactor as purge gas.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The aspects of the disclosed embodiments will now be described, by way of example only, with reference to the accompanying drawings, in which:

FIG. 1 shows a deposition reactor and loading method in accordance with an example embodiment;

FIG. 2 shows the deposition reactor of FIG. 1 in operation during a purge step;

FIG. 3 shows the deposition reactor of FIG. 1 in operation during a first precursor exposure period;

FIG. 4 shows the deposition reactor of FIG. 1 in operation during a second precursor exposure period;

FIG. 5 shows a loading arrangement in accordance with an example embodiment;

FIG. 6 shows a deposition reaction in accordance with another example embodiment;

FIG. 7 a deposition reaction in accordance with yet another example embodiment;

FIG. 8 shows yet another example embodiment;

FIG. 9 more closely shows certain details of a deposition reactor in accordance with certain example embodiments; and

FIG. 10 shows the deposition reactor as a part of a production line in accordance with certain example embodiments.

### DETAILED DESCRIPTION

In the following description, Atomic Layer Deposition (ALD) technology is used as an example. The basics of an ALD growth mechanism are known to a skilled person. As mentioned in the introductory portion of this patent application, ALD is a special chemical deposition method based on the sequential introduction of at least two reactive precursor species to at least one substrate. The substrate, or a batch of substrates in many cases, is located within a reaction space. The reaction space is typically heated. The basic growth mechanism of ALD relies on the bond strength differences between chemical adsorption (chemisorption) and physical adsorption (physisorption). ALD utilizes chemisorption and eliminates physisorption during the deposition process. During chemisorption a strong chemical bond is formed between atom(s) of a solid phase surface and a molecule that is arriving from the gas phase. Bonding by physisorption is much weaker because only van der Waals forces are involved. Physisorption bonds are easily broken by thermal energy when the local temperature is above the condensation temperature of the molecules.

The reaction space of an ALD reactor comprises all the typically heated surfaces that can be exposed alternately and sequentially to each of the ALD precursor used for the deposition of thin films or coatings. A basic ALD deposition cycle consists of four sequential steps: pulse A, purge A, pulse B and purge B. Pulse A typically consists of metal precursor vapor and pulse B of non-metal precursor vapor, especially nitrogen or oxygen precursor vapor. Inactive gas, such as nitrogen or argon, and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness.

In a typical ALD process, precursor species form through chemisorption a chemical bond to reactive sites of the heated surfaces. Conditions are typically arranged in such a way that no more than a molecular monolayer of a solid material forms on the surfaces during one precursor pulse. The growth process is thus self-terminating or saturative. For example, the first precursor can include ligands that remain attached to the adsorbed species and saturate the surface, which prevents further chemisorption. Reaction space temperature is maintained above condensation temperatures and below thermal decomposition temperatures of the utilized precursors such that the precursor molecule species chemisorb on the substrate(s) essentially intact. Essentially intact means that volatile ligands may come off the precursor molecule when the precursor molecules species chemisorb on the surface. The surface becomes essentially saturated with the first type of reactive sites, i.e. adsorbed species of the first precursor molecules. This chemisorption step is typically followed by a first purge step (purge A) wherein the excess first precursor and possible reaction by-products are removed from the reaction space. Second precursor vapor is then introduced into the reaction space. Second precursor molecules typically react with the adsorbed species of the first precursor molecules, thereby forming the desired thin film material or coating. This growth terminates once the entire amount of the adsorbed first precursor has been consumed and the surface has essentially been saturated with the second type of reactive sites. The excess of second precursor vapor and possible reaction by-product vapors are then removed by a second purge step (purge B). The cycle is then repeated until the film or coating has grown to a desired thickness. Deposition cycles can also be more complex. For example, the cycles can include three or more reactant vapor pulses separated by purging steps. All these deposition cycles form a timed deposition sequence that is controlled by a logic unit or a microprocessor.

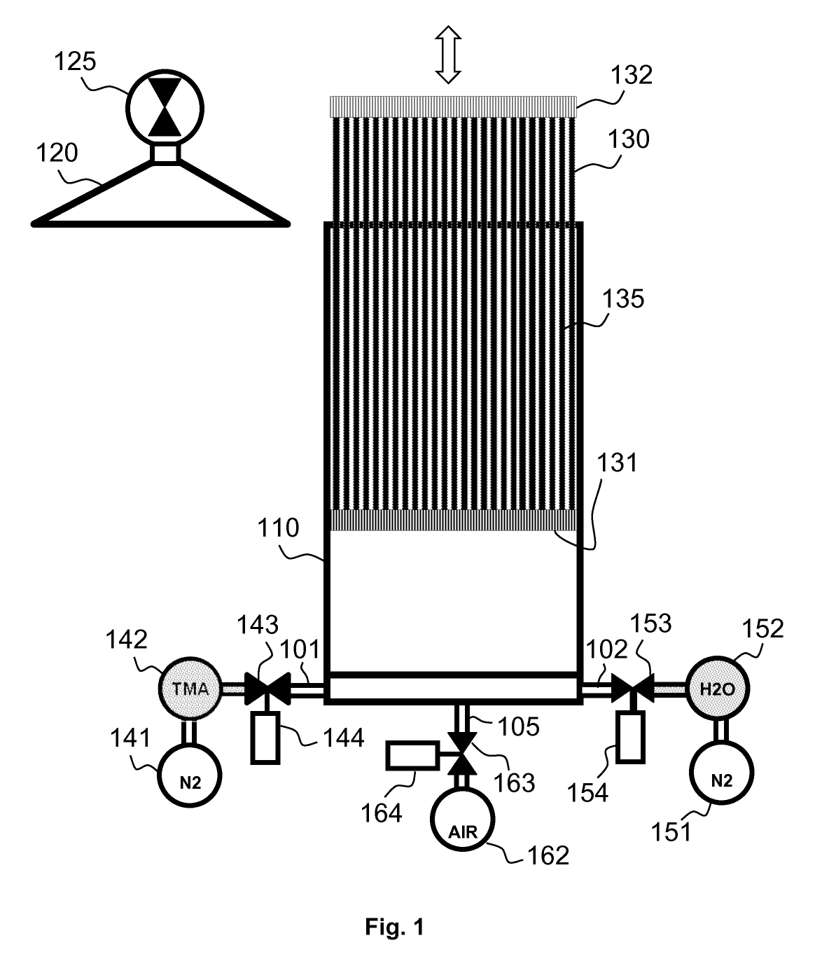

FIG. 1 shows a deposition reactor and loading method in accordance with an example embodiment. The deposition reactor comprises a reactor chamber 110 that forms a space for accommodating a substrate holder 130 carrying at least one substrate 135. Said at least one substrate can actually be a batch of substrates. In the embodiment shown in FIG. 1, the at least one substrate 135 is vertically placed in the substrate holder 130. The substrate holder 130, in this embodiment, comprises a first flow restrictor 131 on its bottom side and a second (optional) flow restrictor 132 on its top side. The second flow restrictor 132 is typically coarser than the first flow restrictor 131. Alternatively, one or both of the flow restrictors 131, 132 may be separate from the substrate holder 130. The reaction chamber 110 is closed by a reaction chamber lid 120 on the top side of the reaction chamber 110. Attached to the lid 120 is an exhaust valve 125.

The deposition reactor comprises precursor vapor in-feed lines 101 and 102 in the bottom section of the deposition reactor. A first precursor vapor in-feed line 101 travels from an inactive carrier gas source 141 via a first precursor source 142 (here: TMA) and through a first precursor in-feed valve 143 into the bottom section of the reaction chamber 110. The first precursor in-feed valve 143 is controlled by an actuator 144. Similarly, a second precursor vapor in-feed line 102 travels from an inactive carrier gas source 151 via a second precursor source 152 (here: H₂O) and through a second precursor in-feed valve 153 into the bottom section of the reaction chamber 110. The second precursor in-feed valve 153 is controlled by an actuator 154. The inactive carrier gas sources 141, 151 may be implemented by a single source or separate sources. In the embodiment shown in FIG. 1, nitrogen is used as the inactive carrier gas. However, in the event that precursor sources that have high vapor pressure are used, carrier gas does not have to be used at all in some instances. Alternatively, in those cases, the route of carrier gas may be such that carrier gas flows via the precursor vapor in-feed line in question, but passes the precursor source in question.

The deposition reactor further comprises a purge gas in-feed line 105 in the bottom section of the deposition reactor. The purge gas in-feed line 105 travels from a purge gas source 162 through a purge gas valve 163 into the bottom section of the reaction chamber 110. The purge gas valve 163 is controlled by an actuator 164. In the embodiment shown in FIG. 1, compressed gas, such as dry air (or dried air) is used as purge gas. Herein, the expressions dry air and dried air mean air without any moisture residue.

The reaction chamber 110 is loaded with a least one substrate by lowering the substrate holder 130 into the reaction chamber 110 from the top side of the deposition reactor. After deposition, the reaction chamber 110 is unloaded in the opposite direction, that is, by raising the substrate holder 110 out of the reaction chamber 110. For the loading and unloading purpose, the lid 120 to the reaction chamber has been moved aside.

As mentioned in the preceding, a deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B). After loading, but before the commencement of the deposition sequence, the reaction chamber 110 is also initially purged.

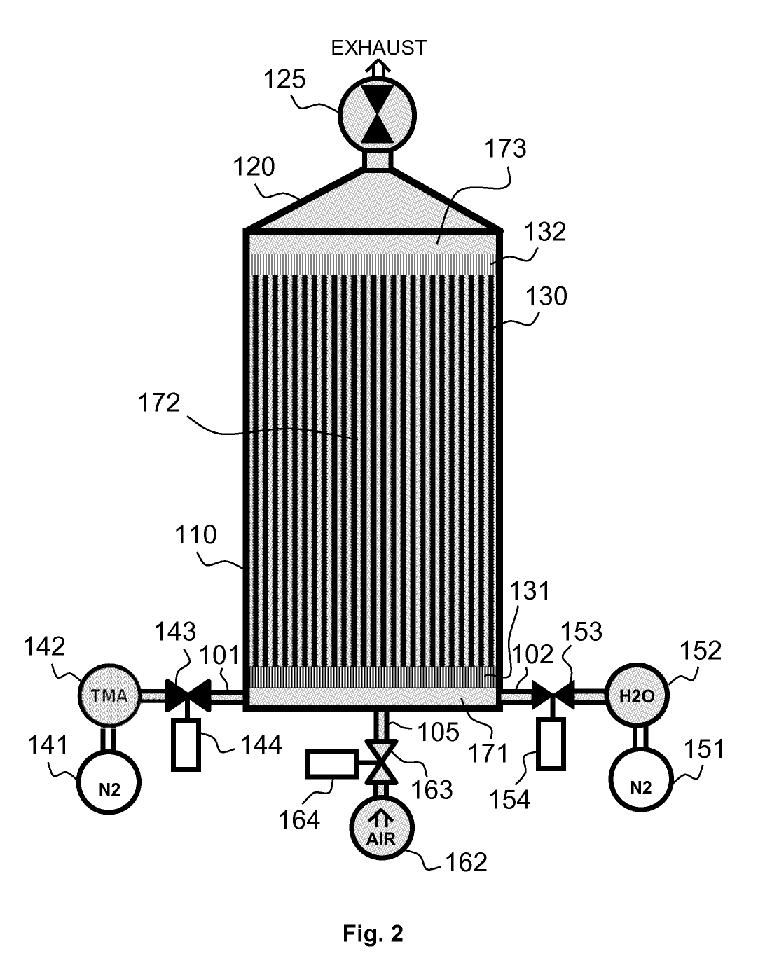

FIG. 2 shows the deposition reactor of FIG. 1 in operation during such a purge phase, that is, during the initial purge or during purge A or purge B.

In this example embodiment, as mentioned in the preceding, compressed gas such as dry air, is used as a purge gas. The purge gas valve 163 is kept open so that the purge gas flows from the purge gas source 162 via the purge gas in-feed line 105 into the reaction chamber 110. The purge gas enters the reaction chamber 110 at an expansion volume 171 upstream the first flow restrictor 131. Due to the flow restrictor 131, the purge gas spreads laterally in the expansion volume 171. The pressure in the expansion volume 171 is higher than the pressure in the substrate area, that is, volume 172. The purge gas flows through the flow restrictor 131 into the substrate area. The pressure in a lid volume 173 downstream the second flow restrictor 132 is lower than the pressure in the substrate area 172 so the purge gas flows from the substrate area 172 through the second flow restrictor 132 into the lid volume 173. From the lid volume 173, the purge gas flows via the exhaust valve 125 to an exhaust channel. During purge A and B the purpose of purging is to push away gaseous reaction by-products and residual reactant molecules. During initial purge the purpose is typically to push away residual humidity/moisture and any impurities.

In an example embodiment, the purge gas is used to heat the reaction chamber 110. The heating by the purge gas can be in operation during the initial purge, or during both the initial purge and the deposition sequence depending on the circumstances. Provided that the compressed gas, such as dry air, used to heat the reaction chamber 110 is inactive with regard the used precursors and used carrier gas (if any), the heating by the purge gas can be in use during the precursor exposure periods (pulse A and pulse B).

In a heating embodiment, the purge gas is heated in the purge gas in-feed line 105. The heated purge gas enters the reaction chamber 110 and heats the reaction chamber 110, and especially the said at least one substrate 135. The used heat transfer method therefore is generally convection, and forced convection in more detail.

Dry air (or dried air) meaning air without any moisture residue can be easily provided, for example, by a conventional clean dry air producing apparatus (clean dry air source) known as such. Such an apparatus can be used as the purge gas source 162.

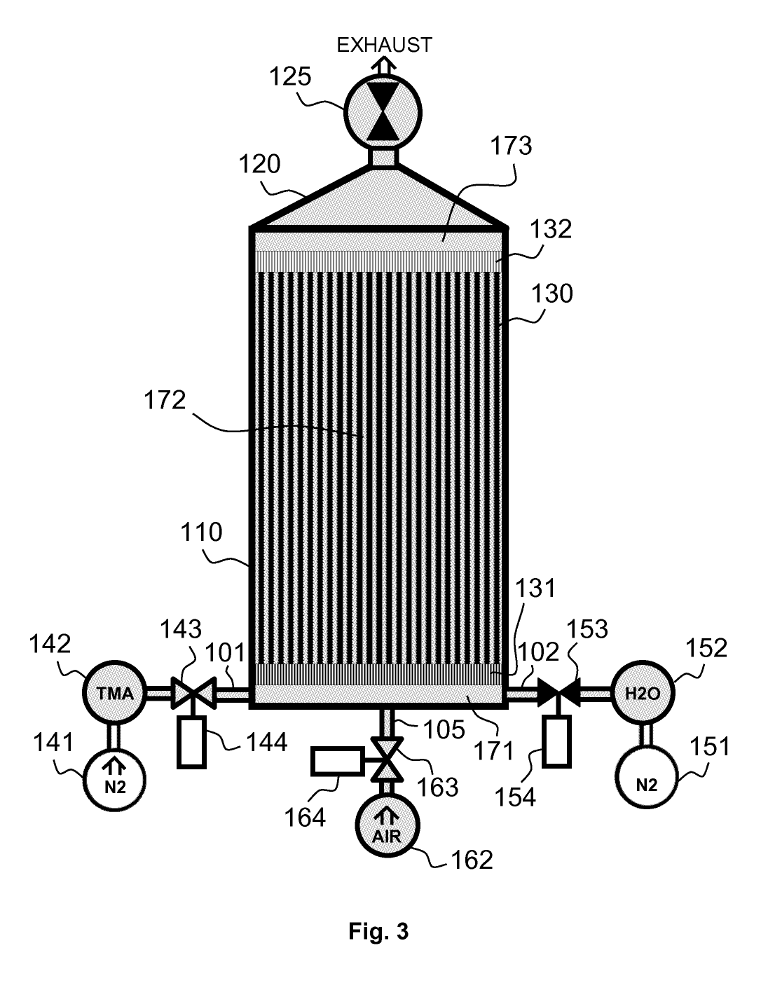

FIG. 3 shows the deposition reactor of FIG. 1 in operation during pulse A where the precursor used (first precursor) is trimethylaluminium TMA. In this embodiment, nitrogen N₂ is used as inactive carrier gas. The inactive carried gas flows via the first precursor source 142 carrying precursor vapor into the reaction chamber 110. Before entering the substrate area 172, the precursor vapor spreads laterally in the expansion volume 171. The first precursor in-feed valve 143 is kept open and the second precursor in-feed valve 153 closed.

Simultaneously, the heated inactive purge gas flows into the reaction chamber 110 via the purge gas line 105 through the opened purge gas valve 163 heating the reaction chamber 110.

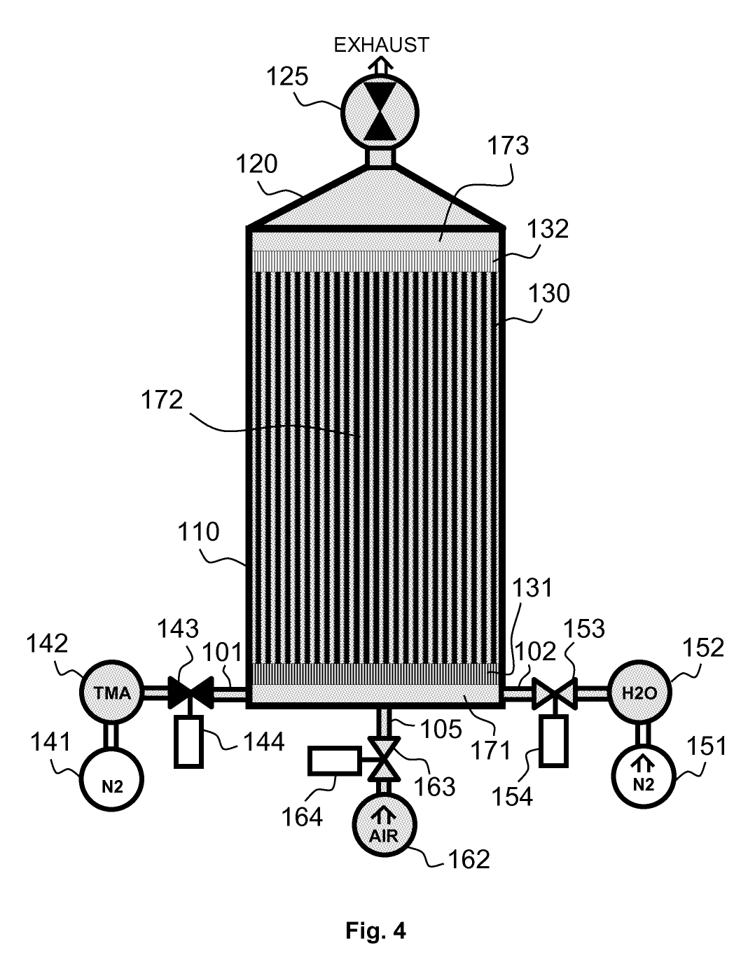

FIG. 4 shows the deposition reactor of FIG. 1 in operation during pulse B where the precursor used (second precursor) is water H₂O. In this embodiment, nitrogen N₂ is used as inactive carrier gas. The inactive carried gas flows via the second precursor source 152 carrying precursor vapor into the reaction chamber 110. Before entering the substrate area 172, the precursor vapor spreads laterally in the expansion volume 171. The second precursor in-feed valve 153 is kept open and the first precursor in-feed valve 143 closed.

Simultaneously, the heated inactive purge gas flows into the reaction chamber 110 via the purge gas line 105 through the opened purge gas valve 163 heating the reaction chamber 110.

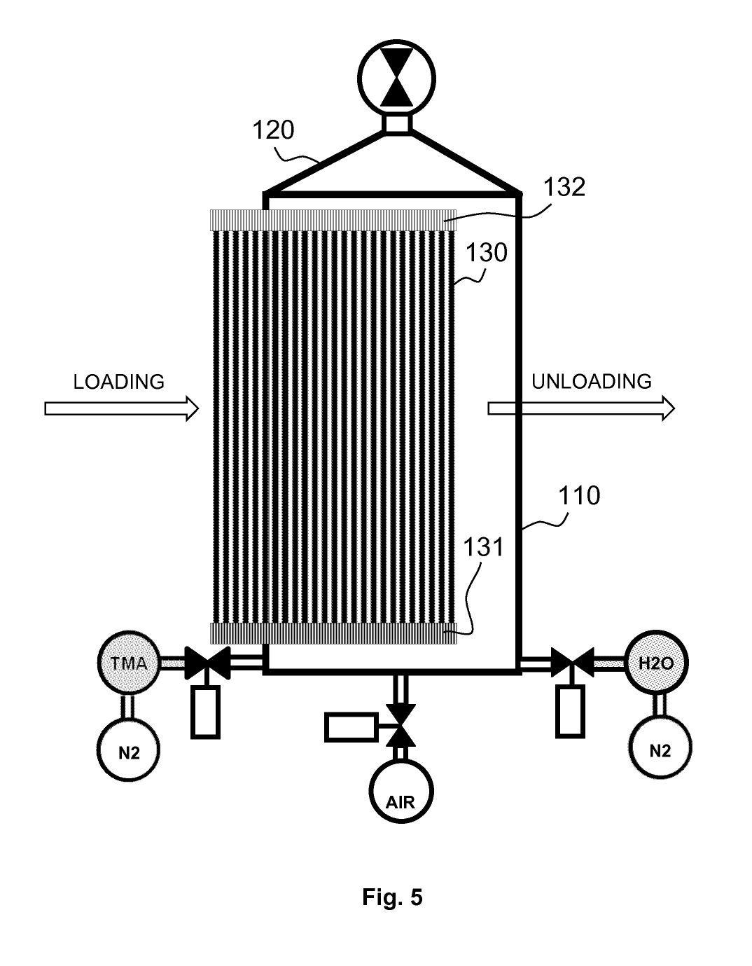

FIG. 5 shows a loading arrangement in accordance with an example embodiment. In this embodiment, the reaction chamber 110 has doors in its sides, and the substrate holder 130 is loaded from a side and unloaded from another side, for example the opposite side. The reaction chamber lid 120 need not be removable.

In certain example embodiments, the deposition sequence in the deposition reactor may be carried out in ambient pressure (typically room pressure), or in a pressure close to one standard atmosphere (1 atm). In these embodiments, a vacuum pump or similar is not needed in the exhaust channel. Also, any vacuum chamber is not needed to accommodate the reaction chamber 110. A pressure vessel can be omitted. A lightweight reactor chamber 110 can be used. The walls of the reaction chamber 110 can be thin, made for example of sheet metal. The walls may be passivated before use by coating them with a passive layer. The ALD method may be used. In fact, the interior surface of the reaction chamber 110 can be passivated beforehand (before deposition sequences on substrates are carried out) using the deposition reactor itself with suitable precursors.

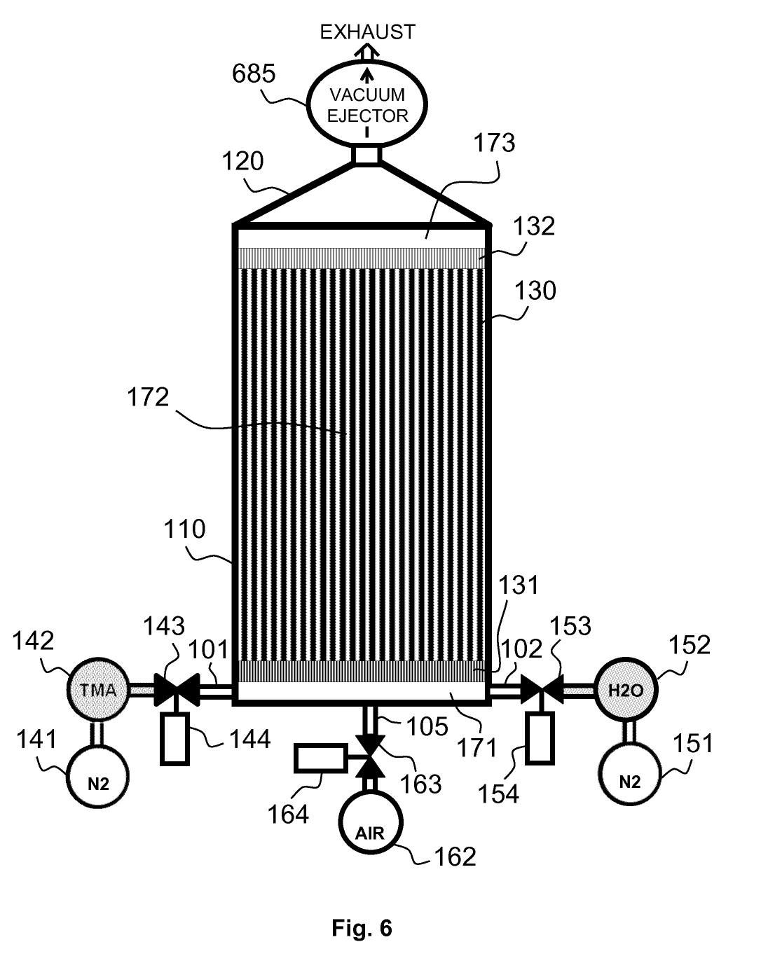

In case it is required to operate below the ambient pressure, the deposition reactor can be provided with a vacuum ejector known as such. FIG. 6 shows such a vacuum ejector 685 attached into the exhaust channel of the deposition reactor. In the vacuum ejector 685, suitable inactive motive gas is inlet into the ejector generating a low pressure zone sucking gas and small particles from the reaction chamber 110 thereby reducing the pressure in the reaction chamber 110.

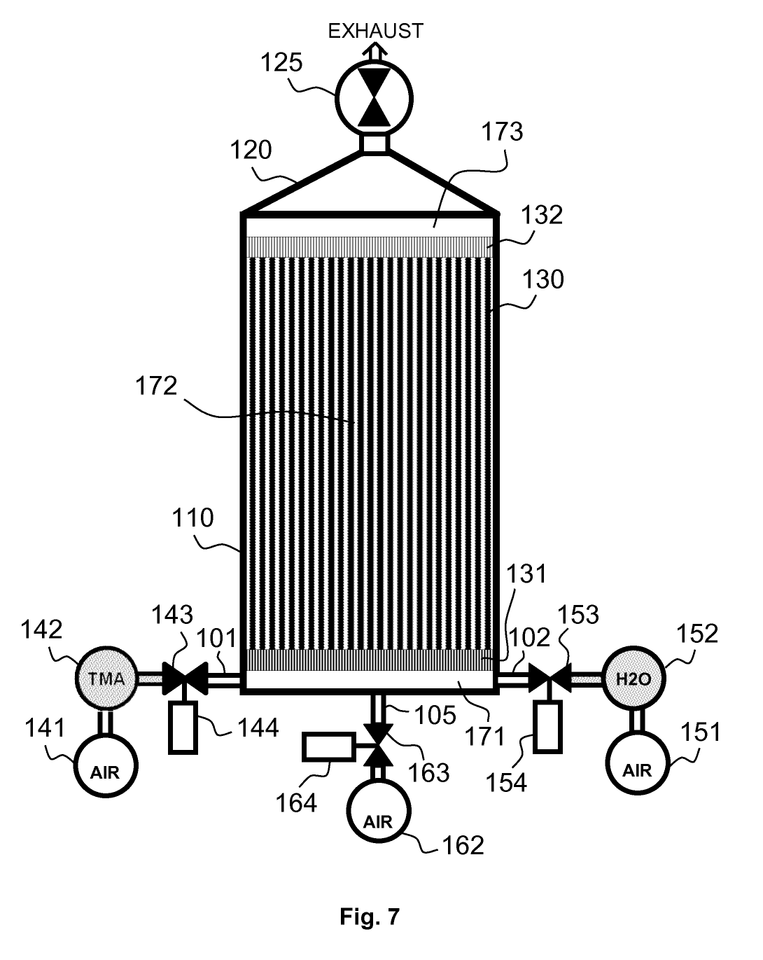

FIG. 7 shows a deposition reaction in accordance with yet another example embodiment. In this embodiment, the same gas that is used as the purge gas in the purge gas line 105 is also used as the inactive carrier gas. During operation, the compressed gas, such as dry air, alternately flows from the source 141 via the first precursor source 142 into the reaction chamber 110 and from the source 151 via the second precursor source 152 into the reaction chamber 110 carrying precursor vapor with it. In addition, the inactive purge gas flows via the purge gas in-feed line 105 into the reaction chamber 110. Alternatively, the route of carrier gas may be such that carrier gas flows via the precursor vapor in-feed line in question, but passes the precursor source in question. In an example embodiment, the inactive carrier gas flows from the inactive gas source in question via the precursor vapor in-feed line in question into the reaction chamber 110 without actually flowing through the precursor source in question. The gas sources 141, 151 and 162 may be implemented by a single source or separate sources.

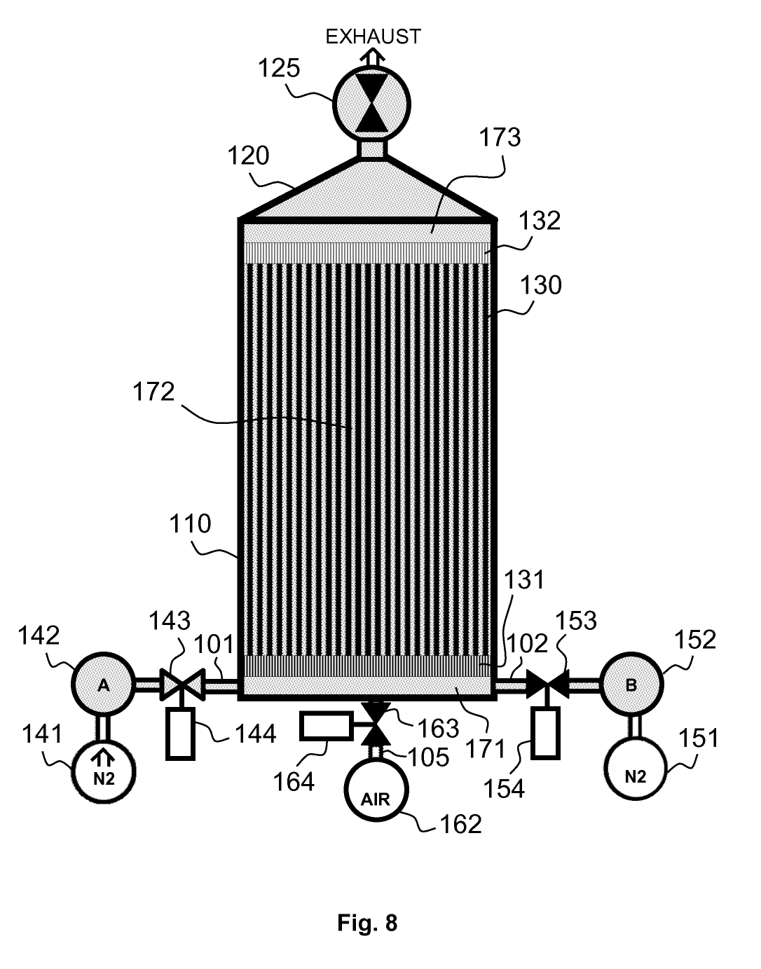

FIG. 8 shows a deposition reaction in accordance with yet another example embodiment. This embodiment is suitable especially for situations in which the purge gas of in the in-feed line 105 cannot be allowed to enter the reaction chamber 110 during the deposition sequence (for example if the purge gas is not inactive with regard to the used precursors). In this embodiment, the purge gas in-feed line 105 is open during the initial purge. During the initial purge, heated purge gas flows from the purge gas in-feed line 105 into the reaction chamber 110 for heating the reaction chamber 110. After the initial purge, the purge gas valve 163 is closed and it remains closed during the whole deposition sequence.

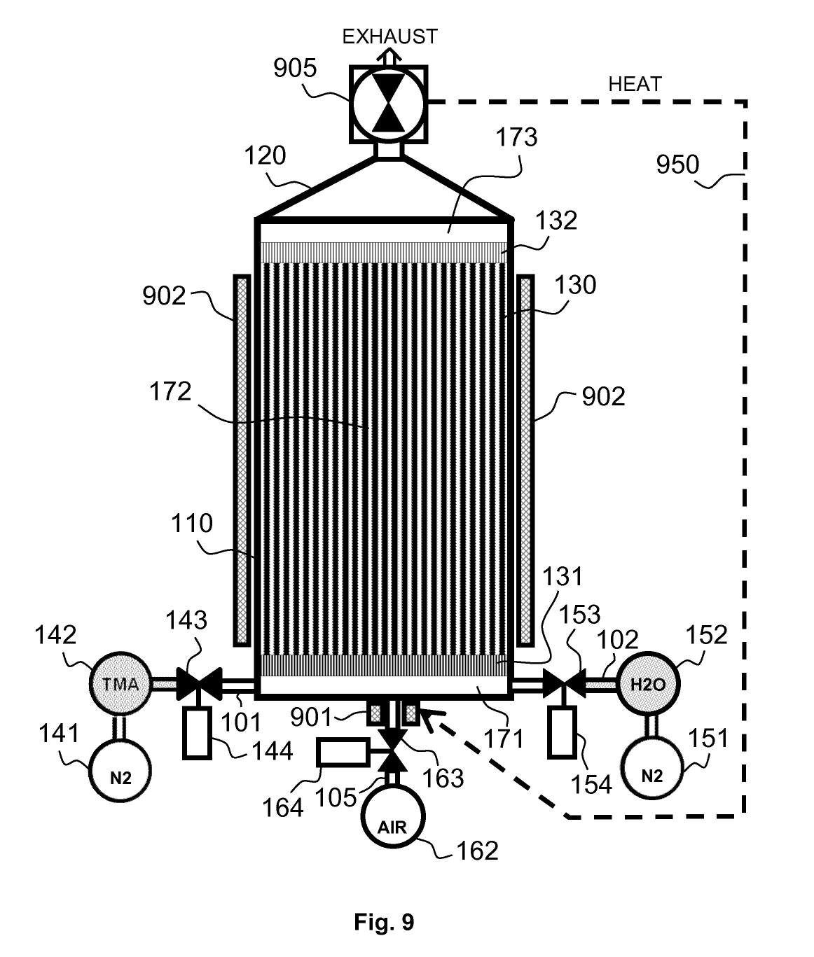

FIG. 9 more closely shows certain details of a deposition reactor in accordance with certain example embodiments. In FIG. 9 there is shown a reaction chamber heater (or heaters) 902, a heat exchanger 905, a purge gas in-feed line heater (or heaters) 901, and a feedback connection of heat 950.

The reaction chamber heater 902 located around the reaction chamber 110 provides the reaction chamber 110 with heat when desired. The heater 902 may be an electrical heater or similar. The used heat transfer method is mainly radiation.

The purge gas in-feed line heater 901 heats, in the in-feed line 105, the purge gas which, in turn, heats the reaction chamber 110. The used heat transfer method is forced convection as described in the foregoing. The location of the gas in-feed line heater 901 in the in-feed line 105 is downstream the purge gas valve 163 in FIG. 9. Alternatively, the location of the purge gas in-feed line heater 901 may be upstream the purge gas valve 163 closer to the purge gas source 162.

The heat exchanger 905 attached to the top part or lid 120 of the reaction chamber or to the exhaust channel can be used to implement the feedback connection 950. In certain embodiments, heat energy collected from the exhaust gases is used in heating the purge gas by the heater 901 and/or the heat energy can be exploited in the heater 902.

In each of the presented embodiments, the reaction chamber lid 120 or the exhaust channel of the deposition reactor can comprise a gas scrubber. Such a gas scrubber comprises active material which absorbs such gases, compounds and/or particles which are not expected to exit from the deposition reactor.

In certain embodiments, the precursor sources 142, 152 may be heated. In their structure the sources 142, 152 may be flow-through sources. The flow restrictors 131, 132, especially the coarser, that is, second flow restrictor 132 may be optional in certain embodiments. If during the deposition sequence the growth mechanism is slow, in certain embodiments the exhaust valve 125 can be closed during pulse A and B, while otherwise opened, in order to reduce precursor consumption. In certain embodiments, the deposition reactor is implemented upside down compared to the embodiments presented herein.

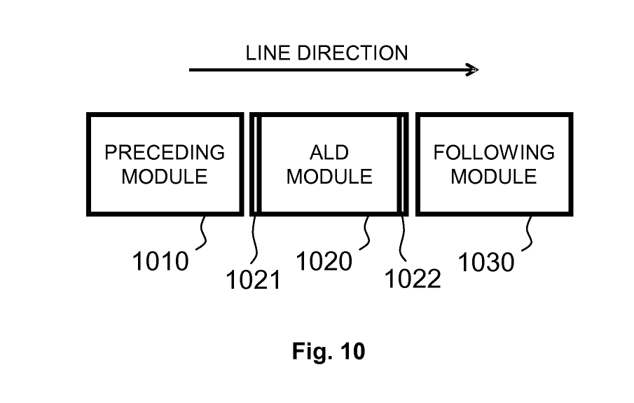

FIG. 10 shows the deposition reactor as a part of a production line, the ALD reactor thus being an in-line ALD reactor (or reactor module). A deposition reactor similar to the ALD reactor presented in the preceding can be used in a production line. The example embodiment of FIG. 10 shows three adjacent modules or machines in a production line. At least one substrate or a substrate holder or cassette or similar carrying said at least one substrate is received from a module or machine 1010 preceding the ALD reactor module 1020 via an input port or door 1021. The at least one substrate is ALD processed in the ALD reactor module 1020 and sent to a following module or machine 1030 via an output port or door 1022 for further processing. The output port or door 1022 may reside at the opposite side of the ALD reactor module than the input port or door 1021.

Without limiting the scope and interpretation of the patent claims, certain technical effects of one or more of the example embodiments disclosed herein are listed in the following: A technical effect is a simpler and more economical deposition reactor structure. Another technical effect is heating or pre-heating the reaction chamber and substrate surfaces by forced convection. Yet another technical effect is the use of dry air as both purge and carrier gas during an ALD deposition sequence. Yet another technical feature is ALD processing in ambient pressure or slightly below the ambient pressure, thereby enabling the ALD reactor/ALD reactor module to be conveniently used in a production line.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A method comprising:
operating an atomic layer deposition reactor configured to deposit material on at least one substrate by sequential self-saturating surface reactions; and
using dry air in the reactor as purge gas.

2. The method of claim 1, comprising:
using dry air as carrier gas.

3. The method of claim 1, comprising:
having dry air to flow into a reaction chamber of the reactor during the whole deposition sequence.

4. The method of claim 1, comprising:
using dry air in heating a reaction chamber of the reactor.

5. The method of claim 1, comprising:
heating the dry air downstream a purge gas in-feed valve.

6. The method of claim 1, comprising:
providing a feedback connection of heat from an outlet part of the reactor to a purge gas in-feed line heater.

7. The method of claim 1, comprising:
operating said atomic layer deposition reactor in ambient pressure to deposit material on at least one substrate by sequential self-saturating surface reactions.

8. The method of claim 1, comprising:
using an ejector attached to an outlet part of the reactor to reduce operating pressure in the reactor.

9. An apparatus comprising:
an atomic layer deposition reaction chamber configured to deposit material on at least one substrate by sequential self-saturating surface reactions; and
a dry air in-feed line from a dry air source to feed dry air as purge gas into a reaction chamber of the reactor.

10. The apparatus of claim 9, comprising:
a precursor in-feed line from a dry air source via a precursor source into the reaction chamber to carry precursor vapor into the reaction chamber.

11. The apparatus of claim 9, comprising:
a heater configured to heat the dry air.

12. The apparatus of claim 11, comprising:
said heater downstream a purge gas in-feed valve.

13. The apparatus of claim 9, comprising:
a feedback connection of heat from an outlet part of the reactor to a purge gas in-feed line heater.

14. The apparatus of claim 9, wherein the reactor is a lightweight reactor configured to operate in ambient pressure or close to the ambient pressure.

15. The apparatus of claim 9, comprising:
an ejector attached to an outlet part of the reactor to reduce operating pressure in the reactor.

16. A production line comprising the apparatus of claim 9 as a part of the production line.

17. An apparatus comprising:
means for operating an atomic layer deposition reactor configured to deposit material on at least one substrate by sequential self-saturating surface reactions; and
means for using dry air in the reactor as purge gas.
